(19) United States
(12) Patent Application Publication
(10) Pub. No.: US 2018/0190776 A1
(43) Pub. Date: Jul. 5, 2018

(54) SEMICONDUCTOR CHIP PACKAGE WITH CAVITY

(71) Applicants: Sireesha Gogineni, Folsom, CA (US); Juan Eduardo Dominguez, Gilbert, AZ (US)

(72) Inventors: Sireesha Gogineni, Folsom, CA (US); Juan Eduardo Dominguez, Gilbert, AZ (US)

(21) Appl. No.: 15/396,217

(22) Filed: Dec. 30, 2016

(51) Int. Cl. H01L 29/18; H01L 23/538; H01L 25/065; H01L 23/31; H01L 23/00; H05K 1/18; H01L 25/00; H01L 21/48; H05K 3/34

(52) U.S. Cl. CPC H01L 29/18; H01L 2224/92247; H01L 25/0657; H01L 23/3128; H01L 24/48; H01L 24/32; H01L 24/73; H01L 24/49; H05K 1/181; H01L 25/50; H01L 24/83; H01L 21/4846; H01L 24/85; H01L 24/92; H05K 3/3436; H01L 2924/15153; H01L 2924/1438; H01L 2924/1432; H01L 2924/1433; H01L 2924/10253; H01L 2924/1207; H01L 2924/1205; H01L 2924/1206; H01L 2224/73265; H01L 2224/32225; H01L 2924/15311; H05K 2201/10734; H05K 2201/10159; H01L 2225/0651; H01L 2225/06562; H01L 2225/0652; H01L 2224/48091; H01L 2224/48106; H01L 2224/48227; H01L 2924/15747; H01L 23/5389

(57) ABSTRACT

Various embodiments disclosed relate to a semiconductor package. The semiconductor package includes a substrate having first and second opposed major surfaces. The substrate further includes a cavity having a first end defined by a portion of the first major surface and a second end defined by a portion of the second major surface. The semiconductor package further includes a first electronic component attached to the first major surface. The first electronic component substantially covers the first end of the cavity. A second electronic component is at least partially disposed within the cavity.

### BACKGROUND

Semiconductor packages include a number of electrical components that are responsible for carrying out various functions. These components, however, can make semiconductor packages too large to fit into certain devices. It is therefore desirable to minimize the size of semiconductor packages.

### BRIEF DESCRIPTION OF THE FIGURES

The drawings illustrate generally, by way of example, but not by way of limitation, various embodiments discussed in the present document.

FIG. 1 is a schematic sectional view of a system 10, in accordance with various embodiments.

FIG. 2 is a flow diagram illustrating a method of forming a package, in accordance with various embodiments.

FIG. 3A and FIG. 3B are respective top and bottom views of a substrate, in accordance with various embodiments.

FIGS. 4A-4E are schematic diagrams showing a process for forming the package, in accordance with various embodiments.

FIG. 5 is a system level diagram, according to an embodiment of the invention.

### DETAILED DESCRIPTION

Reference will now be made in detail to certain embodiments of the disclosed subject matter, examples of which are illustrated in part in the accompanying drawings. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the inventive subject matter, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

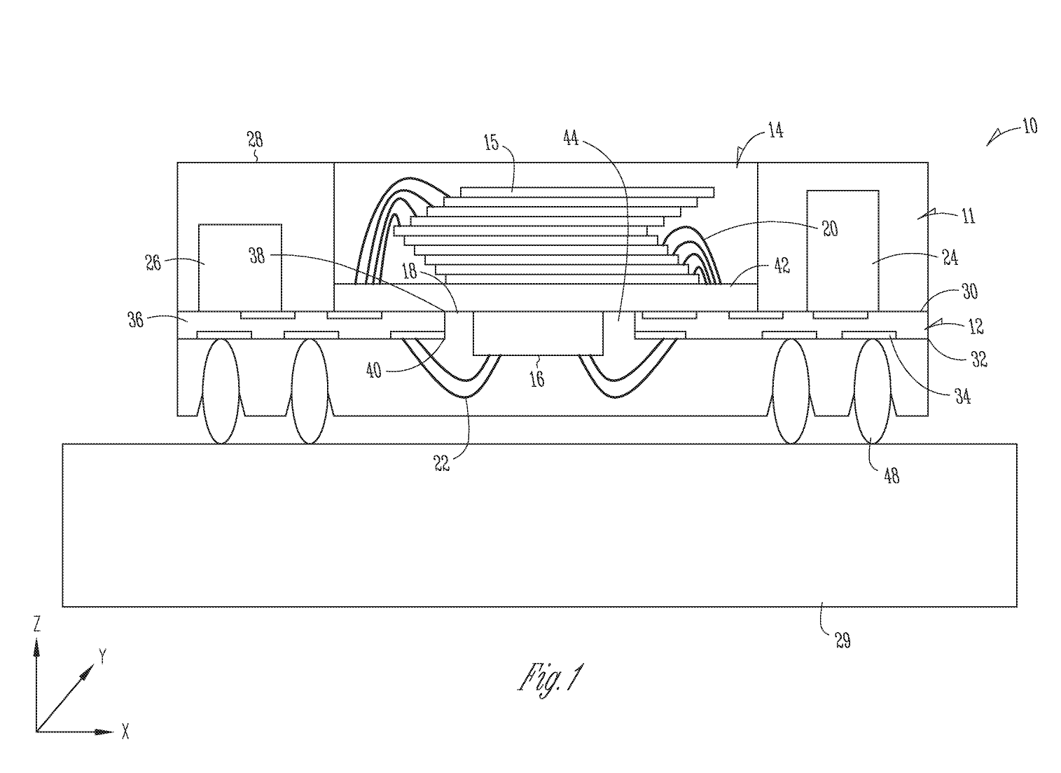

FIG. 1 is a schematic sectional view of a system 10. System 10 includes package 11, substrate 12, first electronic component 14, second electronic component 16, cavity 18, first wire connection 20, second wire connection 22, third electronic component 24, fourth electronic component 26, mold 28, and printed circuit board 29.

Substrate 12 has a z-direction thickness defined between first major surface 30 and second major surface 32. Substrate 12 includes conducting layers 34, which transmit an electronic signal through substrate 12 to first and second wire connections 20, 22 and to third and fourth electronic components 24 and 26. Conducting layers 34 are located proximate to, or on, first major surface 30 and second major surface 32. Conducting layers 34 are dispersed within a silicon or glass interposer medium 36 and are formed from an electronically conductive material. For example, conducting layers 34 may be formed from copper.

Cavity 18 is defined by substrate 12. That is, a portion of first major surface 30 and a portion of second major surface 32 define first end 38 of cavity 18 and second end 40 of cavity 18, respectively. Each end 38, 40 of cavity 18 accounts for a percentage of the surface area of first major surface 30 and second major surface 32, respectively. For example, a surface area of first end 38 of cavity 18 may be in a range from about 10% surface area to about 80% surface area of first major surface 30, or from 40% surface area to about 60% surface area, or less than about, equal to, or greater than about 15% surface area, 20, 25, 30, 35, 40, 45, 50, or 55% surface area. A surface area of second end 40 of cavity 18 may correspondingly be in a range from about 10% surface area to about 80% surface area of second major surface 32, or from 40% surface area to about 60% surface area, or less than about, equal to, or greater than about 15% surface area, 20, 25, 30, 35, 40, 45, 50, or 55% surface area of second major surface 32.

Cavity 18 may have many different profiles. That is, the shape of cavity 18 may be specifically selected from one of many different shapes. For example, each of first end 38 and second end 40 may have a polygonal profile such that cavity 18 is substantially square, substantially rectangular, substantially circular, or substantially elliptically shaped.

First end 38 of cavity 18 is substantially covered by first electronic component 14. As shown in FIG. 1, first electronic component 14 completely covers first end 38. As shown, first electronic component 14 is a multi-die component prepackage including a plurality of dies 15 attached to base 42, which includes third major surface 44. A first portion of third major surface 44 as well as a second portion of third major surface 44 are attached to first major surface 30. Base 42 may be formed from a dielectric material having conductive materials interspersed therein to help provide an electronic signal from substrate 12 to first electronic component 14. Suitable conductive materials within base 44 include copper posts.

First electronic component 14 may be attached to substrate 12 in one of many suitable ways. For example, first electronic component 14 may be adhered to substrate 42 through an adhesive, such as a die attachment film. First electronic component 14 may also be heat compression bonded to substrate 12.

Second electronic component 16 is disposed substantially within cavity 18. That is, a z-direction height of second electronic component 16 may or may not project beyond second end 40 of cavity 18. A portion of second electronic component 16 that extends beyond second end 40 may range from about 5 z-directional height % to about 40 z-directional height % of second electronic component 16, or from about 10 z-directional height % to about 30 z-directional height %, or less than about, equal to, or greater than about 10% z-directional height, 15, 20, 25, 30, or 35 z-directional height % of second electronic component 16.

As illustrated, second electronic component 16 is attached to third major surface 44 of base 42. A spacer may be disposed between second electronic component 16 and base 42. Suitable examples of a spacer may be a die attachment film layer. Second electronic component 16 may also be attached to first electronic component 14 by heat compression bonding or any other suitable technique.

First and second electronic components 14 and 16 are illustrated as silicon dies. Specifically, first electronic component 14 is illustrated as a multi-die component package including a NAND memory stack. Second electronic component 16 is illustrated as an application specific integrated circuit (ASIC). As illustrated the NAND memory stacks include a stack of individual silicon dies 15. The number of silicon dies in the stack may range from 2 to 20 dies or from 4 to 16 dies. First electronic component 14 and second electronic component 16 may be other types of silicon dies. Suitable silicon dies include a central processing unit, a flash memory, a wireless charger, a power management integrated circuit (PMIC), a Wi-Fi transmitter, and a global positioning system.

Although first and second electronic components 14 and 16 are illustrated as silicon dies, they may also be any other suitable electronic component. For example, first and second electronic components 14 and 16 may be a resistor, a capacitor, or an inductor.

First and second electronic components 14 is electronically coupled to base substrate 12 through copper posts or pillars within substrate 12. Individual dies of first electronic component 14 can be electronically coupled to base 42 through first wire connection. Second electronic component 16 is electronically coupled to substrate 12 through second wire connection 22 connects second electronic component 16 to second major surface 32 of substrate 12. Each of wire connections 20 and 22 may include a plurality of wires, as shown in FIG. 1.

Third and fourth electronic components 24 and 26 are attached to first major surface 30 of substrate 12. Third and fourth electronic components 24 and 26 may be many different types of components including a resistor, an inductor, or a capacitor.

Package 11 is attached to printed circuit board 29 through solder balls 48. Solder balls 48 are able to transmit an electronic signal between printed circuit board 29 and package 11. Although FIG. 1 only shows one package 11 attached to printed circuit board 29, there may be additional packages 11 attached to printed circuit board 29 in additional embodiments.

Mold 28 at least partially encases package 11. That is, mold 28 at least partially encases a portion of each of first, second, third, or fourth electronic components 14, 16, 24, and 26; substrate 12; and solder balls 48. Mold 28 protects the components of package 11.

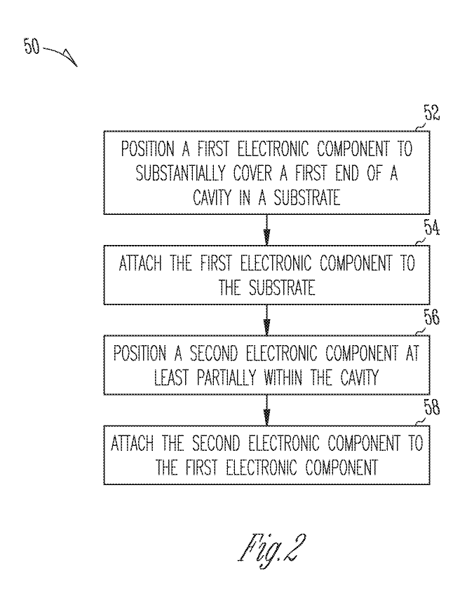

Package 11 may be formed in many suitable ways. FIG. 2 is a flow diagram illustrating method 50 of forming package 11. Method 50 includes process 52, process 54, process 56, and process 58. Process 52 includes positioning first electronic component 14 on substrate 12 to substantially cover first end 38 of cavity 18. Process 54 includes attaching first electronic component 14 to substrate 12. Process 56 includes positioning second electronic component 16 at least partially within cavity 18 Process 58 includes attaching second electronic component 16 to first electronic component 14.

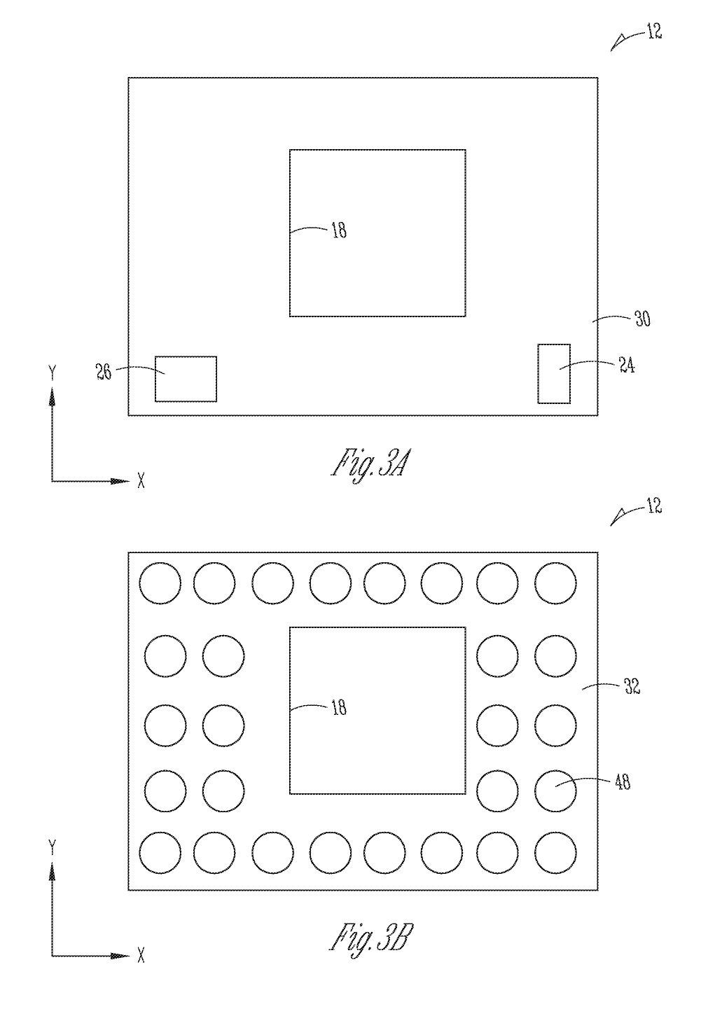

FIG. 3A and FIG. 3B are respective top and bottom views of substrate 12. FIG. 3A shows cavity 18, first major surface 30, and first and second electronic components 24 and 26. FIG. 3B shows cavity 18, second major surface 32, and solder balls 48. As shown, cavity 18 is substantially square shaped. Cavity 18 may be formed in many ways. For example, substrate 12 may be laser etched or milled to form cavity 18. Cavity 18 may be sized to be larger (in the x-y dimension) than that of second electronic component 16, which is disposed therein in package 11.

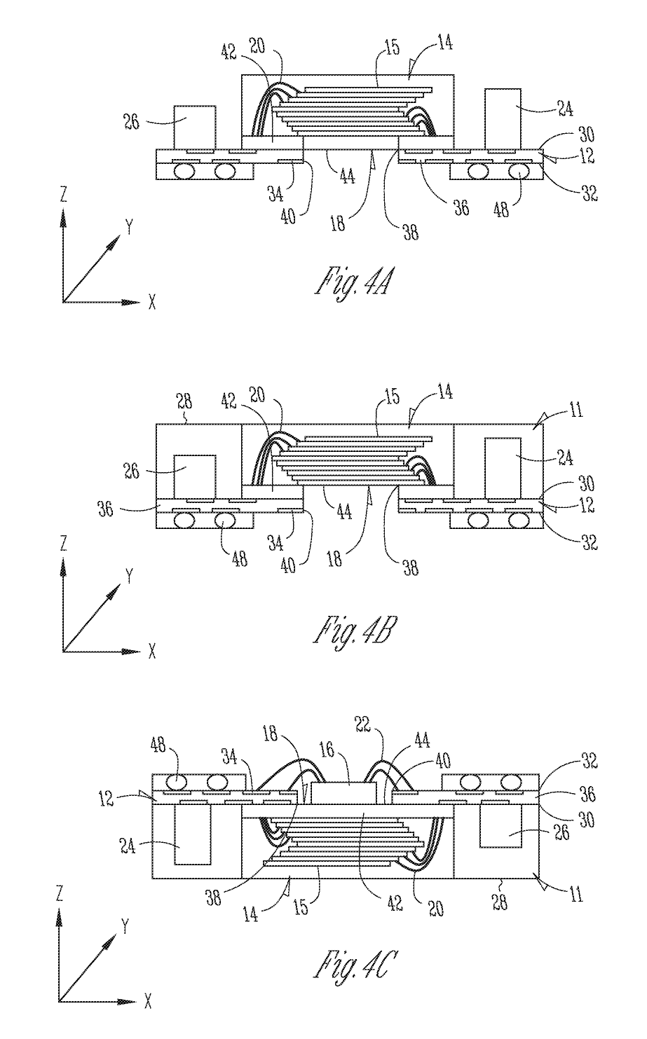

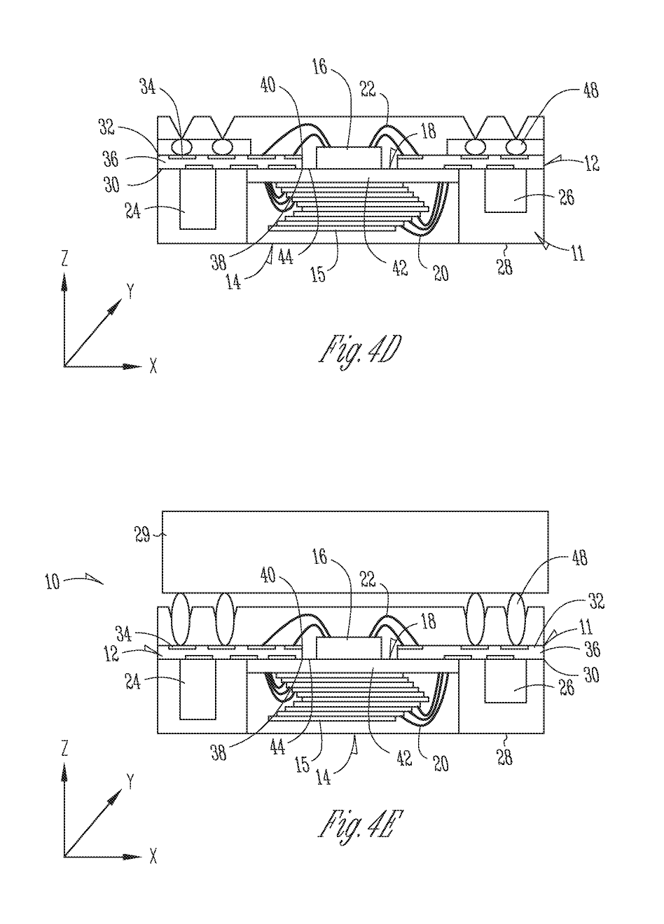

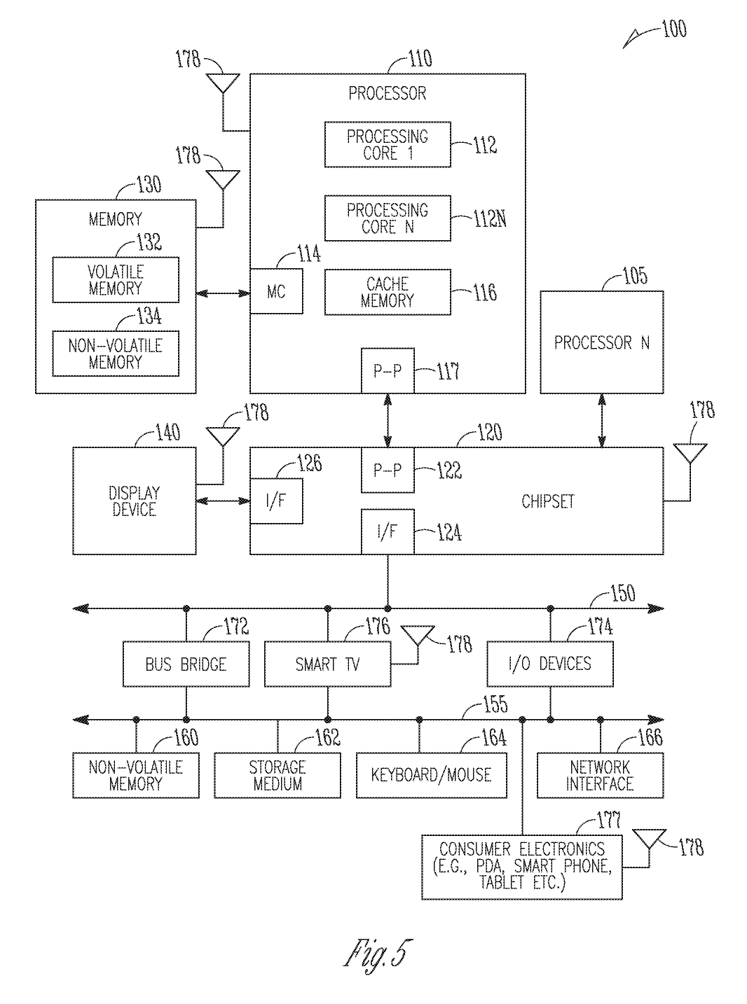

FIGS. 4A-4E are schematic diagrams showing a process for forming package 11. In FIG. 4A, first electronic component 14 is attached to first major surface 30 of substrate 12. First electronic component 14 may be attached through soldering or any other suitable technique. As shown, first electronic component 14 is a NAND package, which includes base 42. In attaching first electronic component 14 to substrate 12, copper posts within base are aligned with conducting layers 34 of substrate 12. This allows an electronic signal to be transmitted from substrate 12 to first electronic component 14. First wire connection 20 electronically connects the individual dies of the stack to base 42.

In other examples of first electronic component 14 that do not include a base, the component 14 may be directly mounted on substrate 12 such that first end 38 of cavity 18 is covered. An electronic connection between substrate 12 and the first electronic component 14 may be through direct contact (e.g., between conducting layer 34 and the first electronic component 14) or through a wire.

FIG. 4B shows package 11 with a portion of mold 28. As shown, mold 28 partially encases first electronic component 14. In other examples, mold 28 may encase first electronic component 14 to a greater or lesser extent. Mold 28 further partially encases third and fourth electronic components 24 and 26 and first major surface 30 of substrate 12.

FIG. 4C shows package 11, with second electronic component 16 partially disposed within cavity 18. Second electronic component 16 may be attached to base 42 through a die attachment film. In examples of package 11 where first electronic component 14 does not include base 42, the die attachment film may be applied directly between first and second electronic components 14 and 16. A die attachment film acts as a spacer such that first and second electronic components 14 and 16 are not in direct contact with each other. Second electronic component 16 is electronically coupled to substrate 12 through second wire connection 22. Because second electronic component 16 is not directly attached to substrate 12, wires are used to electronically connect those components. Other electronic connections between those components are possible. For example, a passive bridge die could be used to connect substrate 12 and second electronic component. 16.

FIG. 4D shows package 11 with another portion of mold 28. As shown, mold 28 partially encases second electronic component 16. In other examples, mold 28 may encase second electronic component 16 to a greater or lesser extent. Mold 28 further partially encases second major surface 32 of substrate 12. Mold also encases solder balls 48. Those portions of mold 28 that encase solder balls 48 are etched to re-expose them.

FIG. 4E shows package 11 after assembly. As shown, solder balls 48 project beyond mold 28. This may be accomplished by pouring material into the etched mold 28. Package 11 is further attached to printed circuit board 29.

FIG. 5 illustrates a system level diagram, according to an embodiment of the invention. For instance, FIG. 5 depicts an example of an electronic device (e.g., system) including system 10, which includes package 11. FIG. 5 is included to show an example of a higher-level device application for the present inventive subject matter. In an embodiment, system 100 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 100 is a system on a chip (SOC) system.

In an embodiment, processor 110 has one or more processing cores 112 and 112N, where 112N represents the Nth processor core inside processor 110, and where N is a positive integer. In an embodiment, system 100 includes multiple processors including 110 and 105, where processor 105 has logic similar or identical to the logic of processor 110. In some embodiments, processing core 112 includes, but is not limited to, pre-fetch logic to fetch instructions, decode logic to decode the instructions, execution logic to execute instructions, and the like. In some embodiments, processor 110 has a cache memory 116 to cache instructions and/or data for system 100. Cache memory 116 may be organized into a hierarchal structure including one or more levels of cache memory.

In some embodiments, processor 110 includes a memory controller (MC) 114, which is operable to perform functions that enable the processor 110 to access and communicate with memory 130, which includes a volatile memory 132 and/or a non-volatile memory 134. In some embodiments, processor 110 is coupled with memory 130 and chipset 120. Processor 110 may also be coupled to a wireless antenna 178 to communicate with any device configured to transmit and/or receive wireless signals. In an embodiment, the wireless antenna 178 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 132 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 134 includes, but is not limited to, flash memory, phase change memory (PCM), read-only memory (ROM), electrically erasable programmable read-only memory (EEPROM), or any other type of non-volatile memory device.

Memory 130 stores information and instructions to be executed by processor 110. In an embodiment, memory 130 may also store temporary variables or other intermediate information while processor 110 is executing instructions. In the illustrated embodiment, chipset 120 connects with processor 110 via Point-to-Point (PtP or P-P) interfaces 117 and 122. Chipset 120 enables processor 110 to connect to other elements in system 100. In some embodiments of the invention, interfaces 117 and 122 operate in accordance with a PtP communication protocol such as the Intel® QuickPath Interconnect (QPI) or the like. In other embodiments, a different interconnect may be used.

In some embodiments, chipset 120 is operable to communicate with processors 110, 105N, display device 140, and other devices 172, 176, 174, 160, 162, 164, 166, 177, etc. Chipset 120 may also be coupled to a wireless antenna 178 to communicate with any device configured to transmit and/or receive wireless signals.

Chipset 120 connects to display device 140 via interface 126. Display device 140 may be, for example, a liquid crystal display (LCD), a plasma display, cathode ray tube (CRT) display, or any other form of visual display device. In some embodiments of the invention, processor 110 and chipset 120 are merged into a single SOC. In addition, chipset 120 connects to one or more buses 150 and 155 that interconnect various elements 174, 160, 162, 164, and 166. Buses 150 and 155 may be interconnected together via a bus bridge 172. In an embodiment, chipset 120 couples with a non-volatile memory 160, a mass storage device(s) 162, a keyboard/mouse 164, and a network interface 166 via interface 124, smart TV 176, consumer electronics 177, etc.

In an embodiment, mass storage device 162 includes, but is not limited to, a solid state drive, a hard disk drive, a universal serial bus flash memory drive, or any other form of computer data storage medium. In an embodiment, network interface 166 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In an embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 100, the functions performed by some of these blocks may be integrated within a single semiconductor circuit or may be implemented using two or more separate integrated circuits. For example, although cache memory 116 is depicted as a separate block within processor 110, cache memory 116 (or selected aspects of cache memory 116) may be incorporated into processing core 112.

There are many reasons to use package 11. For example, the arrangement of the components of package 11 can decrease the overall z-directional height of package 11. The z-directional height of package 11 can impact whether package 11 can be incorporated into various “thin” components such as a tablet or mobile phone where there is an increasing desire to reduce the thickness of those components.

Cavity 18 decreases the contribution to the overall z-directional height of second electronic component 16 to package 18. That is because second electronic component 16 is disposed within cavity 18; thus a smaller portion, if any, of second electronic component 16 projects from substrate 12 than would be the case if second electronic component 16 where placed directly on second major surface 32. Without cavity 18, a possible configuration of a package might be to place second electronic component 16 on either first or second major surface 30, 32 and stack first electronic component 14 on top of second electronic component 16. This may plainly result in the package having a larger z-directional height than that of package 11. This would especially be the case if the first electronic component 14 were a NAND stack. Indeed in package 11, the overall z-directional height, as compared to a corresponding package without cavity 18, is reduced proportionate to the extent that second electronic component 16 is embedded within cavity 18.

Disposing first and second electronic components 14 and 16 can make it easier to diagnose and fix performance problems in package 11. That is, each electronic component 14 and 16 is readily accessible because each component 14, 16 is exposed. Thus a technician can quickly assess each component 14, 16 and make repairs or replacements with minimal impact to package 11. By way of comparison, if first electronic component 14 were stacked on top of second electronic component 16, then in order for a technician to diagnose or fix any problems associated with second electronic component 16, first electronic component 14 would have to be removed and eventually replaced. This would add time and cost to any repairs of second electronic component 16.

Additionally, second wire connection 22 provides a relatively simple way to connect second electronic component 16 to substrate 12. That is, second wire connection 22 does not have to span a large gap; furthermore, given the exposed nature of second wire connection 22, any repairs can be easily accomplished.

### Additional Embodiments

The following exemplary embodiments are provided, the numbering of which is not to be construed as designating levels of importance:

Embodiment 1 provides a semiconductor package comprising:

a substrate having first and second opposed major surfaces;

a cavity having a first end defined by a portion of the first major surface and a second end defined by a portion of the second major surface;

a multi-die component package including a base electronically connected to the first major surface and substantially covering the first end of the cavity; and

a first electronic component at least partially disposed within the cavity.

Embodiment 2 provides the semiconductor package of Embodiment 1, wherein the substrate comprises conducing layers dispersed within silicon.

Embodiment 3 provides the semiconductor package of any one of Embodiments 1 or 2, wherein the conducting layer comprises a conducting material.

Embodiment 4 provides the semiconductor package of Embodiment 3, wherein the conducting material is copper.

Embodiment 5 provides the semiconductor package of any one of Embodiments 1-4, wherein a surface area of the first end of the cavity is in a range from about 10% surface area to about 80% surface area of the first major surface.

Embodiment 6 provides the semiconductor package of any one of Embodiments 1-5, wherein a surface area of the first end of the cavity is in a range from about 40% surface area to about 60% surface area of the first major surface.

Embodiment 7 provides the semiconductor package of any one of Embodiments 1-6, wherein a surface area of the second end of the cavity is in a range from about 10% surface area to about 80% surface area of the second major surface.

Embodiment 8 provides the semiconductor package of any one of Embodiments 1-7, wherein a surface area of the second end of the cavity is in a range from about 40% surface area to about 60% surface area of the second major surface.

Embodiment 9 provides the semiconductor package of any one of Embodiments 1-8, wherein the first end and the second end each have a polygonal profile.

Embodiment 10 provides the semiconductor package of Embodiment 9, wherein the polygonal profile is substantially circular, substantially elliptical, substantially square, or substantially rectangular.

Embodiment 11 provides the semiconductor package of Embodiment 1, wherein the multi-die component package is a NAND memory stack.

Embodiment 12 provides the semiconductor package of Embodiment 1, wherein the multi-die component package includes at least one of a central processing unit, a flash memory, a wireless charger, a power management integrated circuit (PMIC), a Wi-Fi transmitter, a global positioning system, an application specific integrated circuit, and a NAND memory stack.

Embodiment 13 provides the semiconductor package of any one of Embodiments 11 or 12, wherein the silicon die is an application specific integrated circuit.

Embodiment 14 provides the semiconductor package of any one of Embodiments 1-13, wherein the first electronic component is at least one of a silicon die, a resistor, a capacitor, and an inducer.

Embodiment 15 provides the semiconductor package of Embodiment 14, wherein the silicon die is at least one of a central processing unit, a flash memory, a wireless charger, a power management integrated circuit (PMIC), a Wi-Fi transmitter, a global positioning system, an application specific integrated circuit, and a NAND memory stack.

Embodiment 16 provides the semiconductor package of any one of Embodiments 1-15, wherein the base has a third major surface with a first portion attached to the first major surface and a second portion extending across the first end of the cavity.

Embodiment 17 provides the semiconductor package of Embodiment 16, further comprising an adhesive film attached to the third major surface.

Embodiment 18 provides the semiconductor package of any one of Embodiments 1-17, wherein the first electronic component is attached to the base.

Embodiment 19 provides the semiconductor package of Embodiment 18, wherein the first electronic component is attached to the second portion of the base.

Embodiment 20 provides the semiconductor package of any one of Embodiments 1-19, further comprising a first electrical wire connecting the base and a silicon die.

Embodiment 21 provides the semiconductor package of any one of Embodiments 1-20, further comprising a second electrical wire connecting the substrate and the first electronic component.

Embodiment 22 provides the semiconductor package of Embodiment 21, wherein the second electrical wire is attached to the second major surface of the substrate.

Embodiment 23 provides the semiconductor package of any one of Embodiments 1-22, further comprising a second electronic component attached to the first major surface of the substrate.

Embodiment 24 provides the semiconductor package of Embodiment 23, wherein the second electronic component is at least one of a resistor, a capacitor, and an inducer.

Embodiment 25 provides the semiconductor package of any one of Embodiments 1-24, further comprising a plurality of solder balls attached to the second major surface of the substrate.

Embodiment 26 provides the semiconductor package of any one of Embodiments 1-25, further comprising a mold at least partially encapsulating the multi-die component package, the second electronic component, and the substrate.

Embodiment 27 provides a system comprising:

a substrate comprising:
first and second opposed major surfaces;

a cavity having a first end defined by a portion of the first major surface and a second end defined by a portion of the second major surface;

a first silicon die component comprising:
a multi-die component package including a base electronically connected to the first major surface and substantially covering the first end of the cavity;

a second silicon die component at least partially disposed within the cavity and attached to the spacer;

a first plurality of wire bonds between the base and at least one silicon die of the multi-die component package;

a second plurality of wire bonds between the substrate and the second silicon die component;

a printed circuit board attached to the second major surface through an interconnection.

Embodiment 28 provides the system of Embodiment 27, wherein the substrate comprises conducing layers dispersed within silicon.

Embodiment 29 provides the system of any one of Embodiments 27 or 28, wherein the conducting layer comprises a conducting material.

Embodiment 30 provides the system of Embodiment 29, wherein the conducting material is copper.

Embodiment 31 provides the system of any one of Embodiments 27-30, wherein a surface area of the first end of the cavity is in a range from about 10% surface area to about 80% surface area of the first major surface.

Embodiment 32 provides the system of any one of Embodiments 27-31, wherein a surface area of the first end of the cavity is in a range from about 40% surface area to about 60% surface area of the first major surface.

Embodiment 33 provides the system of any one of Embodiments 27-32, wherein a surface area of the second end of the cavity is in a range from about 10% surface area to about 80% surface area of the second major surface.

Embodiment 34 provides the system of any one of Embodiments 27-33, wherein a surface area of the second end of the cavity is in a range from about 40% surface area to about 60% surface area of the second major surface.

Embodiment 35 provides the system of any one of Embodiments 27-34, wherein the first end and the second end each have a polygonal profile.

Embodiment 36 provides the system of any one of Embodiments 27-35, wherein the multi-die component package is a NAND memory stack.

Embodiment 37 provides the system of any one of Embodiments 27-36, wherein the multi-die component package includes at least one of a central processing unit, a flash memory, a wireless charger, a power management integrated circuit (PMIC), a Wi-Fi transmitter, a global positioning system, an application specific integrated circuit, and a NAND memory stack.

Embodiment 38 provides the system of any one of Embodiments 27-37, wherein the second silicon die component is at least one of a central processing unit, a flash memory, a wireless charger, a power management integrated circuit (PMIC), a Wi-Fi transmitter, a global positioning system, an application specific integrated circuit, and a NAND memory stack.

Embodiment 39 provides the system of Embodiment 38, wherein the second silicon die component is an application specific integrated circuit.

Embodiment 40 provides the system of any one of Embodiments 27-39, wherein the first silicon die component comprises a base having a third major surface with a first portion attached to the first major surface and a second portion extending across the first end of the cavity.

Embodiment 41 provides the system of Embodiment 40, further comprising an adhesive film attached to the third major surface.

Embodiment 42 provides the system of any one of Embodiments 27-41 wherein the second silicon die component is attached to the first electronic component.

Embodiment 43 provides the system of any one of Embodiments 27-42, wherein the second silicon die component is attached to the second portion of the base.

Embodiment 44 provides the system of any one of Embodiments 27-43, further comprising an electronic component attached to the first major surface of the substrate.

Embodiment 45 provides the system of Embodiment 44, wherein the electronic component is at least one of a resistor, a capacitor, and an inducer.

Embodiment 46 provides the system of any one of Embodiments 27-45, further comprising a plurality of solder balls attached to the second major surface of the substrate.

Embodiment 47 provides the system of Embodiment 46, wherein each of the plurality of solder balls is attached to the second major surface of the substrate and to the printed circuit board.

Embodiment 48 provides the system of any one of Embodiments 27-47, further comprising a mold at least partially encapsulating the first electronic component, the second electronic component, and the substrate.

Embodiment 49 provides a method of forming a semiconductor chip package comprising:

positioning a base of a multi-die component package to substantially cover a first end of a cavity in a substrate;

attaching the base to the substrate;

positioning a first electronic component at least partially within the cavity; and

attaching the first electronic component to the base of the multi-die component package.

Embodiment 50 provides the method of Embodiment 49, further comprising forming the cavity in the substrate.

Embodiment 51 provides the method of any one of Embodiments 49 or 50, wherein attaching the first electronic component to the substrate comprises bonding the first electronic component to the substrate.

Embodiment 52 provides the method of Embodiment 51, wherein bonding the multi-die component package to the substrate comprises thermally bonding the multi-die component package to the substrate.

Embodiment 53 provides the method of Embodiment 52, further comprising forming a die attachment film on the base.

Embodiment 54 provides the method of any one of Embodiments 49-53, wherein the first electronic component is at least one of a silicon die, a resistor, a capacitor, and an inducer.

Embodiment 55 provides the method of Embodiment 54, wherein the silicon die is at least one of a central processing unit, a flash memory, a wireless charger, a power management integrated circuit (PMIC), a Wi-Fi transmitter, a global positioning system, an application specific integrated circuit, and a NAND memory stack.

Embodiment 56 provides the method of any one of Embodiments 54 or 55, wherein the silicon die is a NAND memory stack.

Embodiment 57 provides the method of any one of Embodiments 49-56, wherein the second electronic component is attached to the die attachment film.

Embodiment 58 provides the method of any one of Embodiments 49-57, further comprising attaching a plurality of solder balls to the substrate.

Embodiment 59 provides the method of Embodiment 58, further comprising attaching the solder balls to a printed circuit board.

Embodiment 60 provides the method of any one of Embodiments 49-59, further connecting a second electrical wire from the substrate to the first electronic component.

1. A semiconductor package comprising:
a substrate having first and second opposed major surfaces;
a cavity having a first end defined by a portion of the first major surface and a second end defined by a portion of the second major surface;
a multi-die component package including a base electronically connected to the first major surface and substantially covering the first end of the cavity; and
a first electronic component at least partially disposed within the cavity.

2. The semiconductor package of claim 1, wherein the multi-die component package is a NAND memory stack.

3. The semiconductor package of claim 1, wherein the multi-die component package includes at least one of a central processing unit, a flash memory, a wireless charger, a power management integrated circuit (PMIC), a Wi-Fi transmitter, a global positioning system, an application specific integrated circuit, and a NAND memory stack.

4. The semiconductor package of claim 1, wherein the first electronic component is at least one of a silicon die, a resistor, a capacitor, and an inductor.

5. The semiconductor package of claim 4, wherein the silicon die is at least one of a central processing unit, a flash memory, a wireless charger, a power management integrated circuit (PMIC), a Wi-Fi transmitter, a global positioning system, an application specific integrated circuit, and a NAND memory stack.

6. The semiconductor package of claim 5, wherein the silicon die is an application specific integrated circuit.

7. The semiconductor package of claim 1, further comprising a mold at least partially encapsulating the multi-die component package, the second electronic component, and the substrate.

8. The semiconductor package of claim 1, further comprising an electrical wire connecting the substrate and the first electronic component.

9. The semiconductor package of claim 1, further comprising an adhesive film attached to the base.

10. A system comprising:
a substrate comprising:
first and second opposed major surfaces;
a cavity having a first end defined by a portion of the first major surface and a second end defined by a portion of the second major surface;
a first silicon die component comprising:
a multi-die component package including a base electronically connected to the first major surface and substantially covering the first end of the cavity;
a second silicon die component at least partially disposed within the cavity and attached to the spacer;
a first plurality of wire bonds between the base and at least one silicon die of the multi-die component package;
a second plurality of wire bonds between the substrate and the second silicon die component; and
a printed circuit board attached to the second major surface through an interconnection.

11. The system of claim 10, further comprising a plurality of solder balls attached to the second major surface of the substrate.

12. The system of claim 11, wherein each of the plurality of solder balls is attached to the second major surface of the substrate and to the printed circuit board.

13. The system of claim 10, wherein the multi-die component package is a NAND memory stack.

14. The system of claim 10, wherein the multi-die component package includes at least one of a central processing unit, a flash memory, a wireless charger, a power management integrated circuit (PMIC), a Wi-Fi transmitter, a global positioning system, an application specific integrated circuit, and a NAND memory stack.

15. The system of claim 10, wherein the second silicon die component is at least one of a central processing unit, a flash memory, a wireless charger, a power management integrated circuit (PMIC), a Wi-Fi transmitter, a global positioning system, an application specific integrated circuit, and a NAND memory stack.

16. The system of claim 10, wherein the second silicon die component is an application specific integrated circuit.

17. A method of forming a semiconductor chip package, comprising:
positioning a base of a multi-die component package to substantially cover a first end of a cavity in a substrate;
attaching the base to the substrate;
positioning a first electronic component at least partially within the cavity; and
attaching the first electronic component to the base of the multi-die component package.

18. The method of claim 17, further comprising forming the cavity in the substrate.

19. The method of claim 17, wherein attaching the multi-die component package to the substrate comprises bonding the package to the substrate.

20. The method of claim 17, wherein the multi-die component package is a NAND memory stack.
